(19) United States
(12) Patent Application Publication
(10) Pub. No.: US 2026/0324312 A1
(43) Pub. Date: Oct. 15, 2026

(54) THIN FILM WITH HIGH DIELECTRIC CONSTANT AND METHOD FOR MANUFACTURING THE SAME

(71) Applicant: Ming Chi University of Technology, New Taipei City (TW)

(72) Inventor: Yu-Ming Huang, New Taipei City (TW)

(21) Appl. No.: 19/260,767

(22) Filed: Jul. 7, 2025

(30) Foreign Application Priority Data
Apr. 10, 2025 (TW) 114113588

(51) Int. Cl. H01L 21/02; H01L 21/28; H10D 64/68

(52) U.S. Cl. CPC H10P 14/6518; H10D 64/0134; H10D 64/685; H10P 14/6506; H10P 14/69391; H10P 14/69392; H10P 14/69395; H10P 14/69396; H10P 14/69433

(57) ABSTRACT

The present invention provides a method for manufacturing a thin film with high dielectric constant, including: preparing a substrate; depositing a rare earth element layer on the substrate; depositing a dielectric material layer on the rare earth element layer; performing an annealing process to migrate and dope at least a portion of rare earth elements in the rare earth element layer into the dielectric material layer to manufacture the thin film with high dielectric constant. According to the present invention, by disposing the rare earth element layer adjacent to the dielectric material layer along with the annealing process, the rare earth element is allowed to be at least partially doped into the dielectric material layer, thereby increasing the dielectric constant of the thin films and improving the internal structural defects of the thin films.

### CROSS-REFERENCE TO RELATED APPLICATION

This application claims the priority of Taiwanese patent application No. 114113588, filed on Apr. 10, 2025, which is incorporated herewith by reference.

### BACKGROUND OF THE INVENTION

### 1. Field of the Invention

The present invention relates to a thin film with high dielectric constant and a manufacturing method thereof, and in particular to a thin film with high dielectric constant and a manufacturing method thereof applied to advanced integrated circuit element structures, wherein the dielectric constant of the thin film is increased through an annealing process.

### 2. The Prior Arts

Transistors are important components in modern electronic products. In complex integrated circuits, such as microprocessors, there are typically hundreds of millions of transistors. Therefore, in order to achieve high integration density, the size of transistors in integrated circuits needs to be minimized as much as possible.

CMOS (complementary metal-oxide-semiconductor) is one of the most widely used transistors technologies, enabling the miniaturization of transistors to achieve excellent unit performance in advanced processes (such as 7 nm and 5 nm). As the size of CMOS unit continues to shrink, the thickness of the gate dielectric layer decreases correspondingly. However, when the thickness of the gate dielectric layer is too small, it may fail to withstand the applied gate voltage, which results in an electron tunneling effect, thereby leading to severe leakage current.

To overcome the performance bottlenecks of conventional materials during the miniaturization process, the approach currently adopted by the industry is replacing conventional silicon dioxide with high dielectric constant (high-k) materials as the gate dielectric layer. However, the high dielectric constant materials still face several challenges in practical applications, such as interface defects in thin films that may lead to degradation of unit performance, and insufficient thin film stability under high temperature or high electric field environments.

### SUMMARY OF THE INVENTION

There is still a need for a thin film with high dielectric constant for improving the quality and reliability of the gate dielectric layer, while increasing the capacitance performance, and reducing the leakage current simultaneously, and enhancing the long-term stability of the device.

In view of the issues encountered in the prior art, the present invention is intended to provide a method for manufacturing a thin film with high dielectric constant, comprising:
preparing a substrate;
depositing a rare earth element layer on the substrate;
depositing a dielectric material layer on the rare earth element layer;
performing an annealing process to migrate and dope at least a portion of rare earth elements in the rare earth element layer into the dielectric material layer to manufacture the thin film with high dielectric constant.

In an embodiment of the present invention, the method may further comprise: depositing a blocking layer on the dielectric material layer before performing the annealing process.

In an embodiment of the present invention, another dielectric material layer can be deposited on the substrate before depositing the rare earth element layer.

In an embodiment of the present invention, a blocking layer can be deposited on the substrate before depositing the other dielectric material layer.

In an embodiment of the present invention, the rare earth element in the rare earth element layer can include at least one of scandium (Sc), yttrium (Y) and lanthanide elements, and the dielectric material layer can include at least one of AlN, HfO₂, ZrO₂, La₂O₃, Al₂O₃ and Si₃N₄.

In an embodiment of the present invention, the blocking layer can include at least one of TaN, TiN, ZrN, CrN, NbN, WN, CoN and MoN.

In an embodiment of the present invention, the dielectric material layer or the blocking layer can be deposited by a first deposition apparatus, wherein the first deposition apparatus can include at least one of an atomic layer deposition (ALD) apparatus, a plasma enhanced atomic layer deposition (PEALD) apparatus, a chemical vapor deposition (CVD) apparatus, a physical vapor deposition (PVD) apparatus, a plasma enhanced chemical vapor deposition (PEALD) apparatus, and a molecular beam epitaxy (MBE) apparatus.

In an embodiment of the present invention, the rare earth element layer can be deposited by a second deposition apparatus, wherein the second deposition apparatus can include at least one of a sputtering apparatus, an evaporation deposition apparatus, a sol-gel apparatus, and a molecular beam epitaxy (MBE) apparatus.

In an embodiment of the present invention, the annealing process can include at least one of rapid thermal annealing (RTA), laser annealing, microwave annealing, furnace annealing, and vacuum annealing.

In addition, the present invention is also intended to provide a thin film with high dielectric constant manufactured by the above manufacturing method.

The effect of the present invention is that the thin film having high dielectric constant materials are able to be manufactured, in which, by disposing the rare earth element layer adjacent to the dielectric material layer along with the annealing process, the rare earth element is allowed to be at least partially doped into the dielectric material layer, thereby increasing the dielectric constant of the thin film and improving the internal structural defects of the thin film.

The effects of the present invention are not limited to the effects described above, and a person skilled in the art can clearly understand other effects not mentioned from the following descriptions.

### BRIEF DESCRIPTION OF THE DRAWINGS

The above and other aspects, features and advantages of the present invention will be more clearly understood from the following detailed description along with the accompanying drawings, in which:

FIG. 1 is a flow chart of a method for manufacturing a thin film with high dielectric constant according to the present invention;

FIG. 2 is a schematic diagram of a stacked structure of a thin film with high dielectric constant according to a first embodiment of the present invention;

FIG. 3 is a schematic diagram of a stacked structure of a thin film with high dielectric constant according to a second embodiment of the present invention;

FIG. 4 is a schematic diagram of a stacked structure of a thin film with high dielectric constant according to a third embodiment of the present invention;

FIG. 5 is a schematic diagram of a stacked structure of a thin film with high dielectric constant according to a fourth embodiment of the present invention;

FIG. 6 is a schematic diagram of a stacked structure of a thin film with high dielectric constant according to a fifth embodiment of the present invention;

FIG. 7 is a diagram of an experimental device for measuring the capacitance of the thin film;

FIG. 8 is a diagram showing the relationship of capacitance (pF) versus voltage (V) of the unannealed thin film according to Experimental Example 1 of the present invention;

FIGS. 9A to 9G are diagrams respectively showing the relationships of capacitance (pF) versus voltage (V) of the annealed thin films according to Experimental Example 1 of the present invention;

FIG. 10 is diagram showing the relationship of capacitance (pF) versus voltage (V) of the unannealed thin film according to Experimental Example 2 of the present invention; and

FIGS. 11A to 11G are diagrams respectively showing the relationships of capacitance (pF) versus voltage (V) of the annealed thin films according to Experimental Example 2 of the present invention.

### DETAILED DESCRIPTION OF THE PREFERRED EMBODIMENT

According to the embodiments described below, the advantages and the features of the present invention and its implementation methods will be understood more clearly. However, the present invention is not limited to the following embodiments, and may be implemented in various forms.

Without arising contradiction, the technical features of any aspect of the present invention may be combined with other aspects of the present invention.

Hereinafter, the embodiments of the method for manufacturing the thin film with high dielectric constant according to the present invention will be described in detail with reference to accompanying drawings. In the description of the embodiments of the present invention, when an arbitrary structure is described as being formed “on” or “under” another structure, such description should be interpreted to include cases where a third structure is interposed therebetween, and cases where these structures are in contact with each other.

The present invention can be applied to the related fields of advanced integrated circuit structure fabrication, mainly in the production of thin films with high dielectric constant, and is applied to advanced integrated circuit elements such as CMOS transistors, etc.

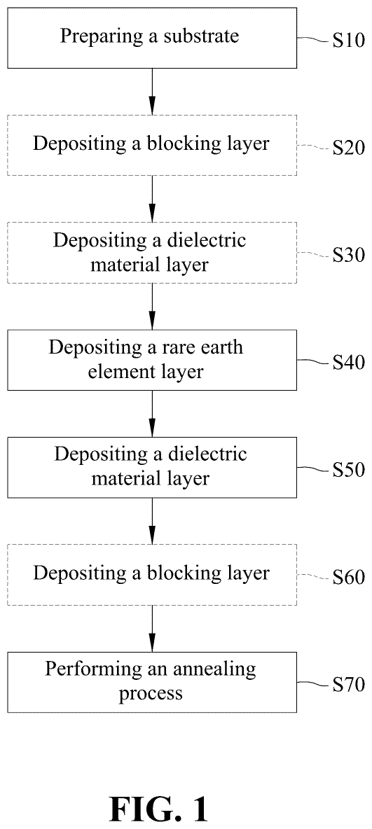

As shown in FIG. 1, the method for manufacturing the thin film with high dielectric constant of the present invention comprises steps S10 to S70, wherein the optional steps are indicated by dashed boxes. The embodiments of the present invention will be described below with reference to FIGS. 1 to 6.

### First Embodiment

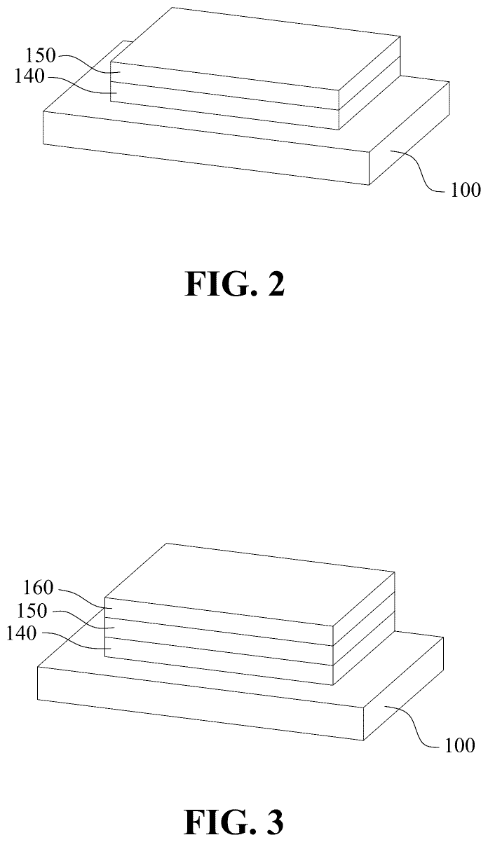

With reference to FIG. 2, the stacked structure of the thin film with high dielectric constant according to the first embodiment of the present invention sequentially comprises: a substrate 100, a rare earth element layer 140, and a dielectric material layer 150.

Therefore, the method for manufacturing the thin film with high dielectric constant according to the first embodiment of the present invention comprises steps S10, S40, S50 and S70.

First, the step S10 preparing the substrate 100 is performed.

The substrate 100 may be a P-type substrate, for example, may be selected from one of a silicon substrate, a germanium substrate, a gallium arsenide substrate, a silicon carbide substrate and a gallium nitride substrate.

Specifically, P-type III-V materials (such as GaAs or GaN) and P-type IV-IV materials (such as silicon carbide) can achieve P-type characteristics through doping.

Then, the step S40 depositing the rare earth element layer 140 on the substrate 100 is performed.

The rare earth element in the rare earth element layer 140 includes at least one of scandium (Sc), yttrium (Y), and lanthanide elements. Wherein, the lanthanide elements include at least one of lanthanum (La), cerium (Ce), praseodymium (Pr), neodymium (Nd), samarium (Sm), titanium (Tm), ytterbium (Yb), and lutetium (Lu).

Preferably, the rare earth element layer 140 is scandium (Sc).

In the step S40, the rare earth element layer 140 may be deposited through a second deposition apparatus.

The second deposition apparatus may include at least one of a sputtering apparatus, an evaporation deposition apparatus, a sol-gel apparatus, and a molecular beam epitaxy (MBE) apparatus.

That is, the rare earth element layer 140 may be deposited by at least one of the methods of sputtering, evaporation deposition, sol-gel process, and molecular beam epitaxy.

Then, the step S50 depositing the dielectric material layer 150 on the rare earth element layer 140 is performed.

The dielectric material layer 150 may include at least one material having high dielectric constant selected from AlN, HfO₂, ZrO₂, La₂O₃, Al₂O₃ and Si₃N₄.

Preferably, the dielectric material layer 150 may be AlN.

In the step S40, the dielectric material layer 150 may be deposited through a first deposition apparatus.

The first deposition apparatus may include at least one of an atomic layer deposition (ALD) apparatus, a plasma enhanced atomic layer deposition (PEALD) apparatus, a chemical vapor deposition (CVD) apparatus, a physical vapor deposition (PVD) apparatus, a plasma enhanced chemical vapor deposition (PECVD) apparatus, and a molecular beam epitaxy (MBE) apparatus.

That is, the dielectric material layer 130 may be deposited by at least one of the methods of atomic layer deposition, plasma enhanced atomic layer deposition, chemical vapor deposition, physical vapor deposition, plasma enhanced chemical vapor deposition, and molecular beam epitaxy.

Preferably, the first deposition apparatus is a PEALD apparatus, which can reduce holes and defects in the thin film and improve the density and electrical performance of the thin film by introducing plasma to activate the reaction.

Specifically, the dielectric material layer 150 may be formed on the rare earth element layer 150 by repeating the deposition process using a PEALD apparatus, wherein the plasma processing technology can accurately control the deposition rate and the thickness of the thin film until the desired film thickness is achieved.

The dielectric material layer 150 may have a thickness between about 3 nm and about 10 nm.

By disposing the rare earth element layer 140 to be adjacent to the dielectric material layer 150, the electric field distribution of the thin film may be adjusted after applying voltage, thereby enhancing the breakdown voltage (Vbd), which in turn allows the components to withstand higher voltages, making it particularly suitable for high-power MOSFET or DRAM capacitor structures; and the thermal stability of the thin film can be enhanced, the crystalline phase change after high-temperature annealing can be reduced, thereby improving the process yield.

Then, the step S70 is performed, wherein an annealing process is performed to migrate and dope at least a portion of rare earth elements in rare earth element layer 140 into dielectric material layer 150 to manufacture the thin film with high dielectric constant.

The reason for performing the annealing process is that the rare earth elements can be doped into the dielectric material layer 150, thereby providing the following effects: enhancing the dielectric constant to reduce leakage current; stabilizing the material structure to suppress unnecessary crystallization; reducing the interface traps to improve electron mobility; adjusting the work function to optimize CMOS gate design; and improving thermal stability and reliability to reduce charge capture.

These advantages make the rare earth-doped thin film with high dielectric constant particularly suitable for CMOS, especially in advanced processes below 10 nm, which is crucial for improving the performance and lifespan of semiconductor.

Furthermore, in addition to be a heat treatment technology, the annealing process can also improve material characteristics, reduce defects, and adjust interface states, etc., when applied to semiconductor process.

The annealing process may include at least one of rapid thermal annealing (RTA), laser annealing, microwave annealing, furnace annealing, and vacuum annealing.

Typically, laser annealing has the advantages of small heating area (precision) and extremely short heating time (nanosecond to microsecond level).

Therefore, preferably, the annealing process may be laser annealing.

Hereinafter, the same reference numerals as those in FIG. 2 denote the same materials.

### Second Embodiment

With reference to FIG. 3, the stacked structure of the thin film with high dielectric constant according to the second embodiment of the present invention sequentially comprises: a substrate 100, a rare earth element layer 140, a dielectric material layer 150, and a blocking layer 160.

Compared with the first embodiment, the thin film with high dielectric constant of the second embodiment further comprises the blocking layer 160 on the dielectric material layer 150.

Therefore, the method for manufacturing the thin film with high dielectric constant according to the second embodiment of the present invention comprises steps S10, S40, S50, S60 and S70.

That is, compared with the first embodiment, the method for manufacturing the thin film with high dielectric constant of the second embodiment further comprises the step S60 between the steps S50 and S70.

In the step S60, before performing the annealing process in the step S70, the blocking layer 160 is deposited on the dielectric material layer 150 deposited in the step S50.

The main function of the blocking layer 160 is to increase the ferroelectric effect, thereby providing higher capacitance storage capacity and lower power consumption.

On the other hand, the blocking layer 160 additionally functions to: inhibiting charge migration to avoid the drift of the work function; inhibiting the diffusion of the oxygen ions to reduce oxygen vacancies and improve the stability of the dielectric layer; decreasing the electron tunneling effect to reduce gate leakage current and improve power consumption efficiency; blocking the diffusion of the metal ions to prevent the materials from degradation, and thereby improving reliability; and improving and reducing the interface defects to improve electron mobility and reduce leakage current.

The blocking layer 160 may include at least one of TaN, TiN, ZrN, CrN, NbN, WN, CoN and MoN.

Preferably, the blocking layer 160 may be TaN or TiN.

The blocking layer 120 (described later) and the blocking layer 160 may be deposited using the same deposition apparatus and deposition method as the dielectric material layer 150, and thus will not be described below.

The blocking layer 160 may have a thickness between about 3 nm and about 10 nm.

### Third Embodiment

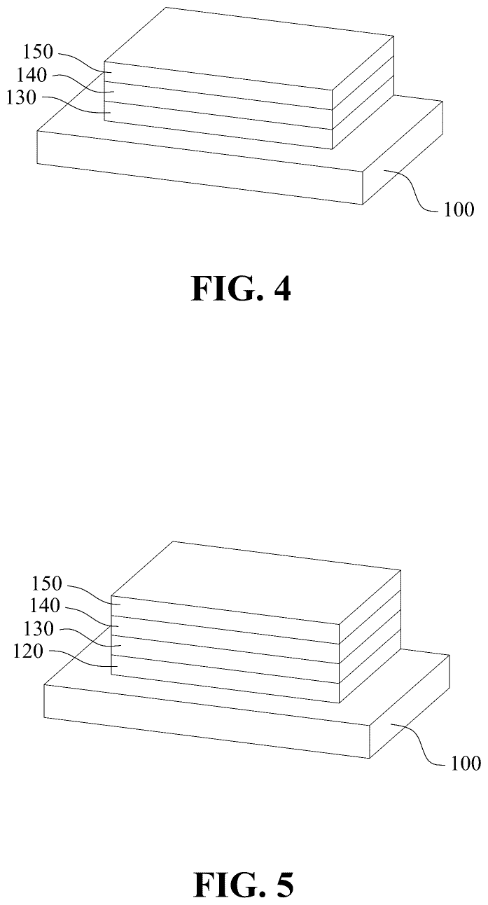

With reference to FIG. 4, the stacked structure of the thin film with high dielectric constant according to the third embodiment of the present invention sequentially comprises: a substrate 100, a dielectric material layer 130, a rare earth element layer 140, and a dielectric material layer 150.

Compared with the first embodiment, the thin film with high dielectric constant of the third embodiment further comprises another dielectric material layer 130 between the rare earth element layer 140 and the substrate 100.

Therefore, the method for manufacturing the thin film with high dielectric constant according to the third embodiment of the present invention comprises steps S10, S30, S40, S50 and S70.

That is, compared with the first embodiment, the method for manufacturing the thin film with high dielectric constant of the third embodiment further comprises a step S30 between the steps S10 and S40.

In the step S30, before performing the deposition of the rare earth element layer 140 in the step S40, the dielectric material layer 130 is deposited on the substrate 100.

Then, the steps S40, S50, and S70 are performed in the same manners as in the first embodiment, to sequentially deposit the rare earth element layer 140 on the dielectric material layer 130, deposit the dielectric material layer 150 on the rare earth element layer 140, and then perform the annealing process.

The dielectric material layer 130 may be formed using the same material, deposition method or deposition apparatus as the dielectric material layer 150, and may have the same features as the dielectric material layer 150, and thus will not be described below.

### Fourth Embodiment

With reference to FIG. 5, the stacked structure of the thin film with high dielectric constant according to the fourth embodiment of the present invention sequentially comprises: a substrate 100, a blocking layer 120, a dielectric material layer 130, a rare earth element layer 140, and a dielectric material layer 150.

Compared with the third embodiment, the thin film with high dielectric constant of the fourth embodiment further comprises the blocking layer 120 between the dielectric material layer 130 and the substrate 100.

Therefore, the method for manufacturing the thin film with high dielectric constant according to the fourth embodiment of the present invention comprises steps S10, S20, S30, S40, S50 and S70.

That is, compared with the third embodiment, the method for manufacturing the thin film with high dielectric constant of the fourth embodiment further comprises a step S20 between the steps S10 and S30.

In the step S20, before performing the deposition of the dielectric material layer 130 in the step S30, the blocking layer 120 is deposited on the substrate 100.

Then, the steps S30, S40, S50 and S70 are performed in the same manners as the third embodiment, to sequentially deposit the dielectric material layer 130 on the blocking layer 120, deposit the rare earth element layer 140 on the dielectric material layer 130, deposit the dielectric material layer 150 on the rare earth element layer 140, and then perform the annealing process.

The blocking layer 120 may be formed using the same material, deposition method or deposition apparatus as the blocking layer 160, and may have the same features as the blocking layer 160, and thus will not be described below.

### Fifth Embodiment

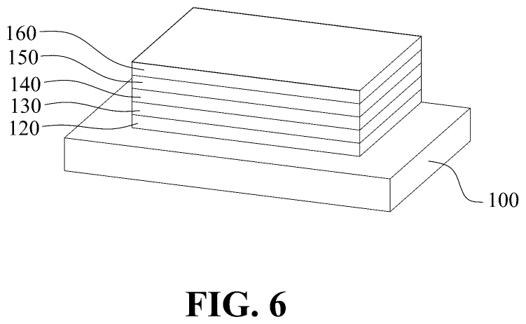

With reference to FIG. 6, the stacked structure of the thin film with high dielectric constant according to the fifth embodiment of the present invention sequentially comprises: a substrate 100, a blocking layer 120, a dielectric material layer 130, a rare earth element layer 140, a dielectric material layer 150, and a blocking layer 160.

Compared with the fourth embodiment, the thin film with high dielectric constant of the fifth embodiment further comprises the blocking layer 160 on the dielectric material layer 150.

Therefore, the method for manufacturing the thin film with high dielectric constant according to the fifth embodiment of the present invention comprises steps S10, S20, S30, S40, S50, S60 and S70.

That is, compared with the third embodiment, the method for manufacturing the thin film with high dielectric constant of the fifth embodiment further comprises a step S60.

In the step S60, before performing the annealing process in the step S70, another blocking layer 160 is deposited on the dielectric material layer 150 deposited in the step S50.

The blocking layer 160 may be formed using the same material, deposition method or deposition apparatus as the blocking layer 120, and may have the same features as the blocking layer 120, and thus will not be described below.

In an embodiment of the present invention, the thickness of the blocking layer 120 may be 10 nm, and the thickness of the blocking layer 160 may be 3 nm.

It should be noted that in the present invention, the blocking layer 120, the dielectric material layer 130, and the blocking layer 160 are optional structures, and thus the step S20, S30, or S60 may be omitted.

In a preferred embodiment, different deposition methods can be selected to grow the thin film according to the manufacturing method of the present invention.

For TiN/AlN thin films of the dielectric material layers or the blocking layers, the PEALD method can be used for deposition, because the PEALD method can achieve extremely high uniformity and has extremely high control capability to thin film thickness, and is particularly suitable for nano-scale dielectric material layers (such as AlN) or blocking layers (such as TiN).

For the Sc metal thin film of the rare earth element layer, sputtering can be used for deposition. As a physical vapor deposition (PVD) technology, sputtering has a deposition rate usually faster than ALD, and is suitable for the deposition of large-area metal thin films. The metal thin films (such as Sc) have relatively lower requirements for interface quality than those of the dielectric material layers or the blocking layers, and thus sputtering can meet its requirements and reduce the time and cost of the process.

In addition, in any embodiment of the present invention, in order to form a stacked structure that meets functional requirements, before performing the step S70, that is, before performing the annealing process, at least one of the blocking layer 120, the dielectric material layer 130, the rare earth element layer 140, the dielectric material layer 150, and the blocking layer 160 may be etched, such as by yellow-light photolithography etching process.

The etching apparatus may include wet etching apparatus, dry etching apparatus, and the like.

### Experimental Examples

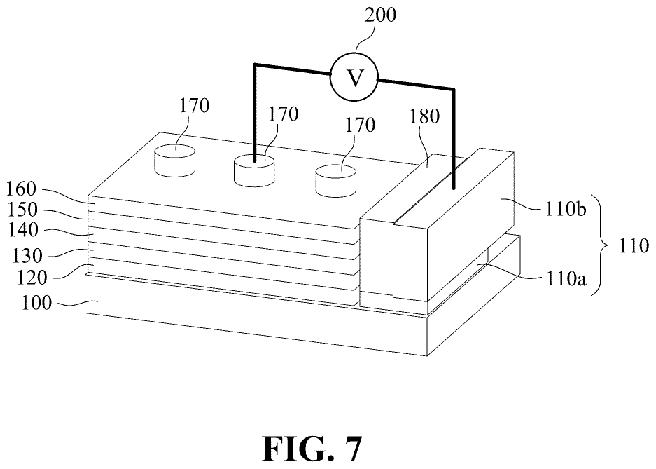

To verify the efficacy of the thin film with high dielectric constant of the present invention, the capacitance of the thin film is measured using an experimental device as shown in FIG. 7.

As shown in FIG. 7, before or after performing the annealing process, a first electrode 110 (lower electrode) electrically connected to the blocking layer 120 and a second electrode 170 (upper electrode) electrically connected to the blocking layer 160 may be formed, respectively, and a sacrificial region 180 may be formed between the stacked structure of the dielectric material layer 130, the rare earth element layer 140, the dielectric material layer 150, the blocking layer 160 and the second electrode 170, and the first electrode 110.

In addition to serving as a temporary structure to ensure the shape layout and size accuracy of other critical areas and improve process yield and uniformity, the sacrificial region 180 can also provide functions of protection and isolation, to electrically isolate the dielectric material layer 130, the rare earth element layer 140, the dielectric material layer 150, the blocking layer 160 and the second electrode 170 from the first electrode 110, thereby avoiding leakage current or short circuit during the capacitance measurement.

Specifically, aluminum thin films may be deposited as the first electrode 110 and the second electrode 170 using a sputtering device.

Also, as shown in FIG. 7, in order to facilitate the connection of two terminals of a measuring device 200 (e.g, a capacitance meter, an electric meter, etc., but not limited thereto), the first electrode 110 as the lower electrode may be extended to a position close to the second electrode 170 as the upper electrode.

In this case, the second electrode 170 can be disposed on the blocking layer 160; and the first electrode 110 can include: a first portion 110a, located at the bottom and adjacent to the dielectric material layer 130; and a second portion 110b, extending upward from the first portion 110a to a position at a height that is the same or similar to that of the second electrode 170, to facilitate the connection to one terminal of the measuring device 200.

The configuration of FIG. 7 is an experimental device used when measuring the thin film (before and after annealing) according to the fifth embodiment of the present invention.

In the case of measuring the thin films according to the first to fourth embodiments of the present invention, although not shown in the figures, a similar configuration can also be used, and it differs from the fifth embodiment only in that: the first electrode 110 (lower electrode) is electrically connected to the bottom layer of the thin film except for the substrate 100, the second electrode 170 (upper electrode) is electrically connected to the top layer of the thin film (for example, formed on the top layer), and the sacrificial region 180 is formed between the first electrode 110 and the layers of the thin film except for the substrate 100 and the bottom layer.

The results of measurement of the capacitance of the thin film with high dielectric constant of the present invention will be further illustrated below.

### Experimental Example 1

First, a thin film with a stacked structure of AlN (dielectric material layer, 10 nm)/Sc (rare earth element layer, 4 nm)/AlN (dielectric material layer, 10 nm) is prepared on a P-type silicon wafer substrate.

Wherein, the AlN layer is deposited by PEALD, and the Sc layer is deposited by sputtering.

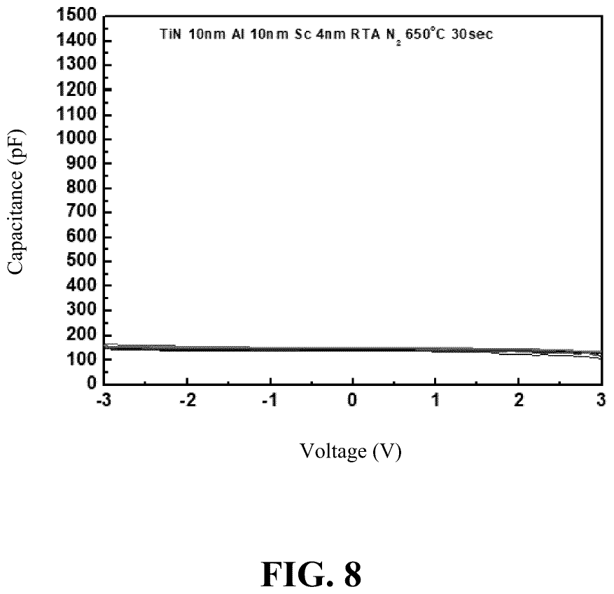

The capacitance of the unannealed thin film is measured using the experimental device described above, which is plotted as a diagram showing the relationship of capacitance (pF) versus voltage (V) (FIG. 8).

As shown in the characteristic curve of FIG. 8, when the thin film is not subjected to laser annealing, its capacitance value (i.e., the dielectric constant) is only 100 to 200 pF (about 100 to 150 pF). This is because if the laser annealing is not performed, a lower dielectric constant may result from issues such as increased internal structural defects in the material, discontinuities in the lattice structure or uneven internal stress, etc.

Subsequently, a UV laser annealing is performed under a nitrogen (N₂) atmosphere, at a wavelength of 355 nm, with laser power intensities ranging from 1S to 7S, respectively, and at 650 °C, for 30 seconds.

Each intensity is repeatedly tested 5 times. 1S indicates the lowest power intensity, and 7S indicates the highest power intensity.

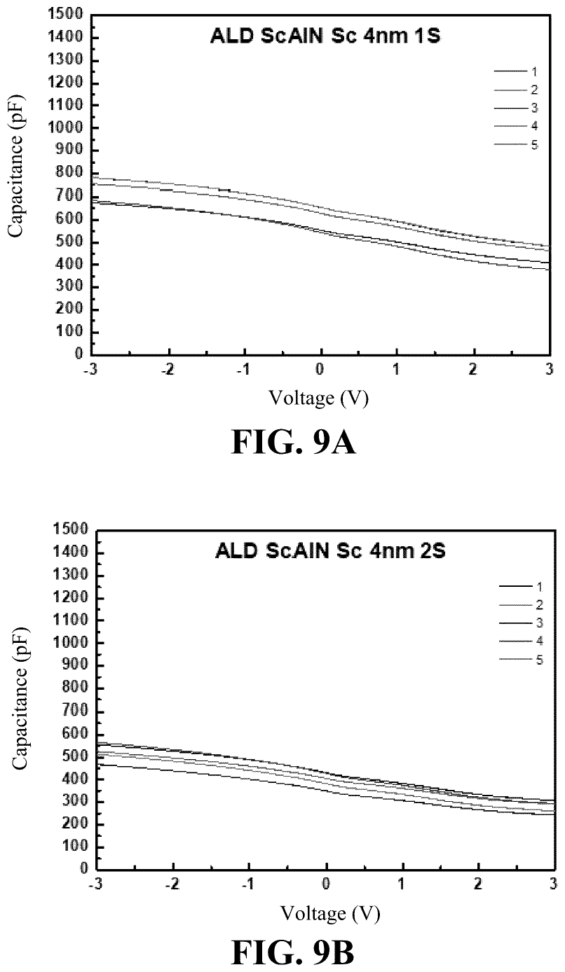

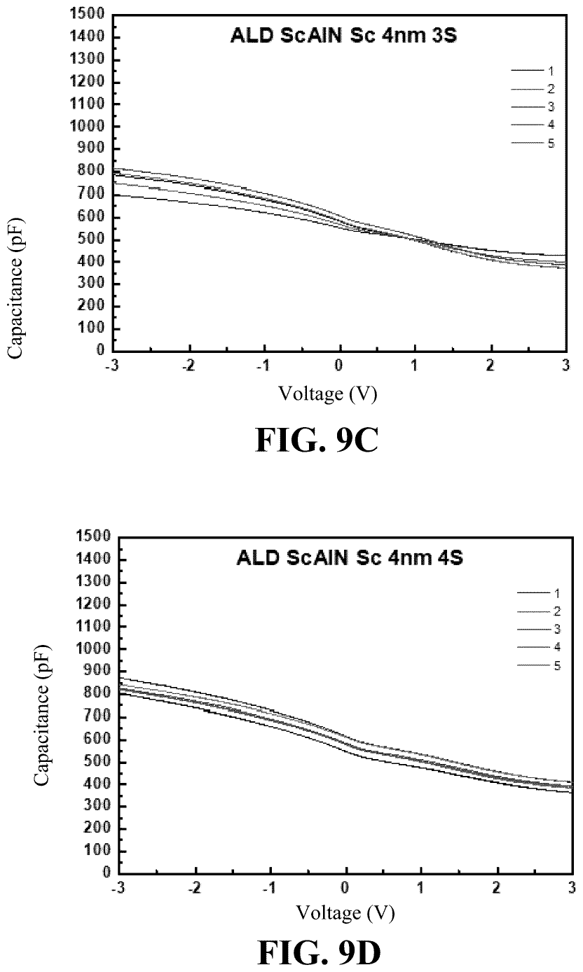

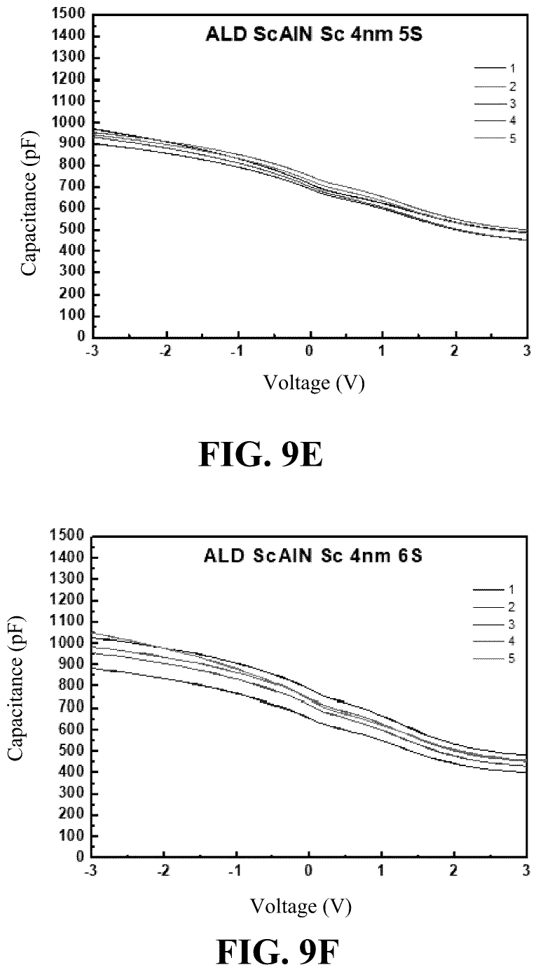

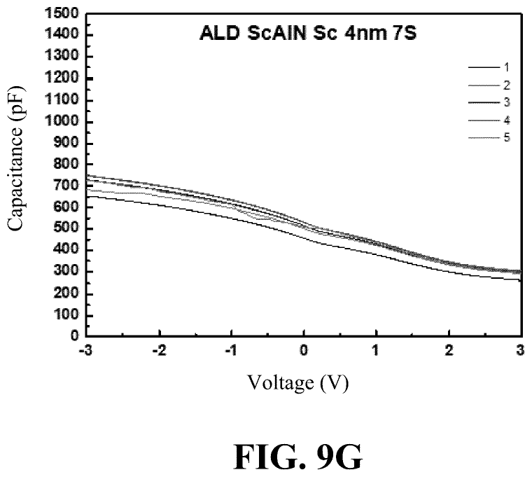

The capacitance of the annealed thin film with high dielectric constant is measured using the experimental device described above, which is plotted as diagrams showing the relationships of capacitance (pF) versus voltage (V) (FIGS. 9A to 9G).

The characteristic curves of FIGS. 9A to 9G show that the capacitance value of the thin films can be increased to 600 to 1000 pF after the annealing process. From the results, it can be seen that the capacitance value can indeed be increased after laser annealing.

### Experimental Example 2

First, a thin film is prepared and its capacitance is measured in the same manner as Experimental Example 1, except that the rare earth element layer of Sc is formed with a thickness of 6 nm.

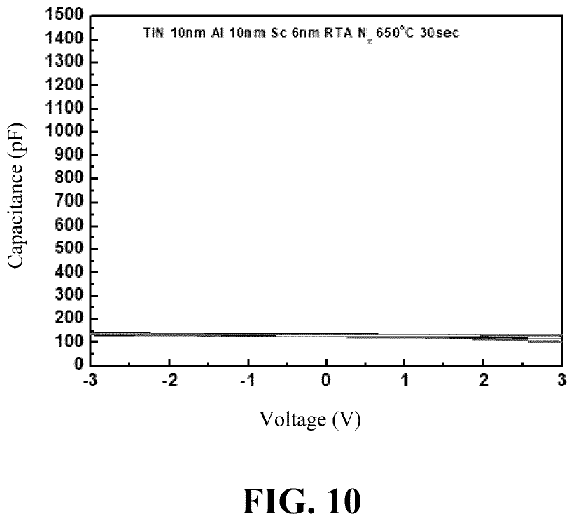

The relationship of capacitance (pF) versus voltage (V) of the unannealed thin film is shown in FIG. 10.

In this experimental example, similar to the characteristic curve of Experimental Example 1 (FIG. 8), when the thin film is not subjected to annealing process, its capacitance value is only 100 to 200 pF (about 100 to 150 pF).

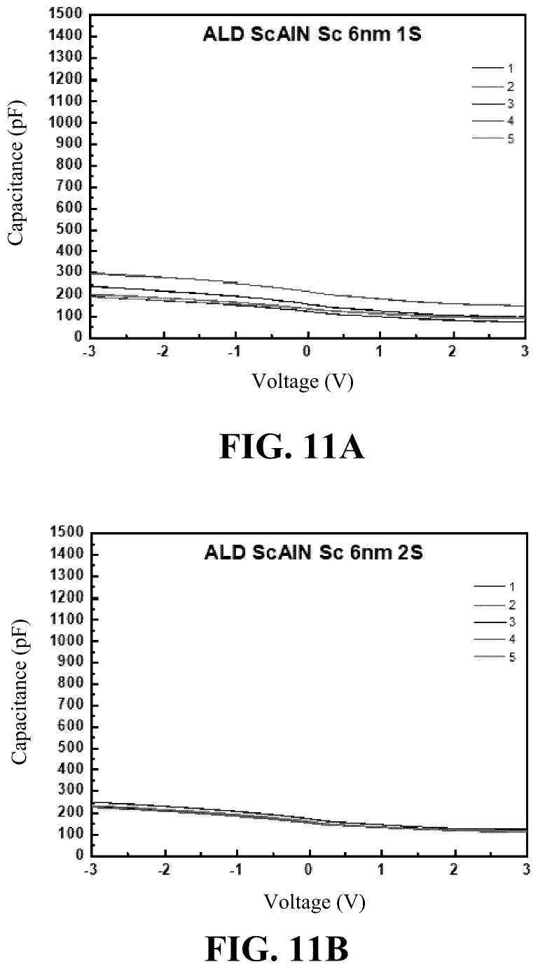

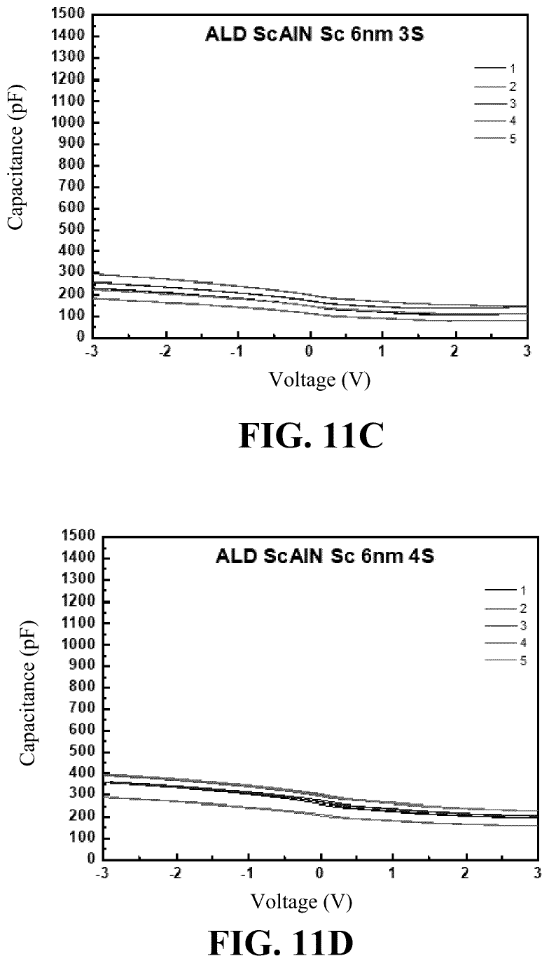

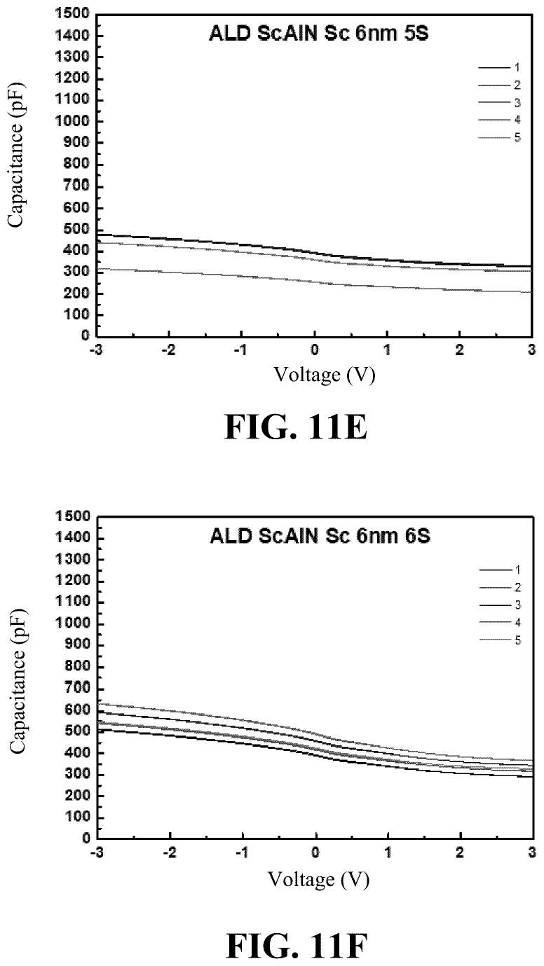

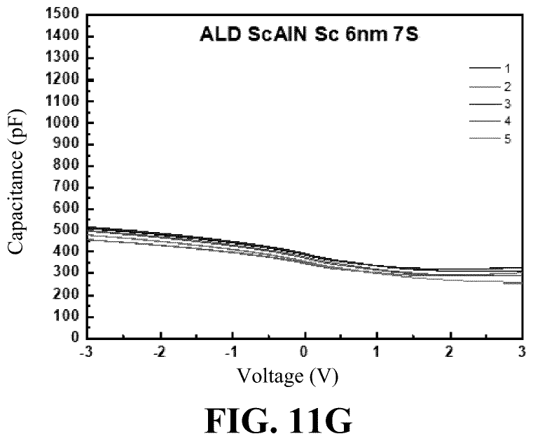

Subsequently, an annealing process is performed in the same manner as Experimental Example 1, and the relationships of capacitance (pF) versus voltage (V) of the annealed thin film is plotted in FIGS. 11A to 11G.

The characteristic curves of FIGS. 11A to 11G show that the capacitance of the thin film can be increased to 300 to 600 pF after the annealing process. This could be attributed to the fact that, when the rare earth element layer is relatively thick (6 nm), the conductive properties of the rare earth metal itself may suppress the polarization effect at the interface between the metal and the dielectric layer, thereby slightly reducing the dielectric constant.

However, even when the rare earth element layer has a thickness of 6 nm, the capacitance value is still increased from about 100 to 150 pF to 300 to 600 pF compared to the unannealed thin film, indicating that regardless of the thickness of the rare earth element layer, the thin film manufactured by the method of the present invention has an improved capacitance value, and is a thin film with high dielectric constant.

In summary, the effect of the present invention is that a thin film having high dielectric constant materials is able to be manufactured, in which, by disposing the rare earth element layer to be adjacent to the dielectric material layer along with the annealing process, the rare earth element is allowed to be at least partially doped into the dielectric material layer, thereby increasing the dielectric constant of the thin film and improving the internal structural defects of the thin film.

A person skilled in the art will understand that various modifications and changes can be made to the above embodiments, such as combinations, separations, substitutions, and configuration changes, without departing from the fundamental features of the present invention.

Therefore, the embodiments of the present invention are intended to illustrate the scope of the technical concept of the present invention, but the scope of the present invention is not limited by the above embodiments. Therefore, any modifications or changes to the present invention made under the same creative spirit should still be included in the scope to be protected of the present invention.

What is claimed is:

1. A method for manufacturing a thin film with high dielectric constant, comprising:
preparing a substrate;
depositing a rare earth element layer on the substrate;
depositing a dielectric material layer on the rare earth element layer;
performing an annealing process to migrate and dope at least a portion of rare earth elements in the rare earth element layer into the dielectric material layer to manufacture the thin film with high dielectric constant.

2. The method according to claim 1, further comprising:
depositing a blocking layer on the dielectric material layer before performing the annealing process.

3. The method according to claim 1, further comprising:
depositing another dielectric material layer on the substrate before depositing the rare earth element layer.

4. The method according to claim 3, further comprising:
depositing a blocking layer on the substrate before depositing the other dielectric material layer.

5. The method according to claim 1, wherein
the rare earth element in the rare earth element layer includes at least one of scandium (Sc), yttrium (Y) and lanthanide elements, and
the dielectric material layer includes at least one of AlN, HfO₂, ZrO₂, La₂O₃, Al₂O₃ and Si₃N₄.

6. The method according to claim 2, wherein the blocking layer includes at least one of TaN, TiN, ZrN, CrN, NbN, WN, CoN and MoN.

7. The method according to claim 2, wherein the dielectric material layer or the blocking layer is deposited through a first deposition apparatus, wherein
the first deposition apparatus includes at least one of an atomic layer deposition (ALD) apparatus, a plasma enhanced atomic layer deposition (PEALD) apparatus, a chemical vapor deposition (CVD) apparatus, a physical vapor deposition (PVD) apparatus, a plasma enhanced chemical vapor deposition (PEALD) apparatus, and a molecular beam epitaxy (MBE) apparatus.

8. The method according to claim 1, wherein the rare earth element layer is deposited by a second deposition apparatus, wherein
the second deposition apparatus includes at least one of a sputtering apparatus, an evaporation deposition apparatus, a sol-gel apparatus, and a molecular beam epitaxy (MBE) apparatus.

9. The method according to claim 1, wherein the annealing process includes at least one of rapid thermal annealing (RTA), laser annealing, microwave annealing, furnace annealing, and vacuum annealing.

10. A thin film with high dielectric constant manufactured by the method according to claim 1.
